(19) United States
(12) Patent Application Publication
(10) Pub. No.: US 2025/0055428 A1
(43) Pub. Date: Feb. 13, 2025

(54) OPERATIONAL AMPLIFIER AND SEMICONDUCTOR DEVICE

(71) Applicant: ROHM CO., LTD., Kyoto-shi (JP)

(72) Inventor: Yusaku YOSHIMATSU, Kyoto-shi (JP)

(21) Appl. No.: 18/788,274

(22) Filed: Jul. 30, 2024

(30) Foreign Application Priority Data
Aug. 9, 2023 (JP) 2023-130314

(51) Int. Cl. H03F 3/45

(52) U.S. Cl. CPC H03F 3/45269

(57) ABSTRACT

An operational amplifier includes: an input circuit including a PMOS input differential pair and an NMOS input differential pair, an operating input differential pair being switchable between the PMOS input differential pair and the NMOS input differential pair; a current generation circuit structured to generate a reference current; and an output circuit through which an idling current that increases according to an increase in the reference current flows, and structured to generate an output voltage according to output signals of the PMOS input differential pair and the NMOS input differential pair. The current generation circuit is structured to make the reference current larger in a case where a decreasing condition of the idling current is satisfied than in a case where the decreasing condition is not satisfied.

### CROSS REFERENCE TO RELATED APPLICATIONS

The present invention claims priority under 35 U.S.C. § 119 to Japanese Application No. 2023-130314, filed on Aug. 9, 2023, the entire contents of which being incorporated herein by reference.

### BACKGROUND

### 1. Technical Field

The present disclosure relates to an operational amplifier and a semiconductor device.

### 2. Description of the Related Art

Operational amplifiers are used to amplify a difference between two input voltages. Japanese Patent Application (Laid Open) No. 2021-132357 discloses an operational amplifier including a P-channel metal oxide semiconductor (PMOS) input differential pair including a P-cannel MOS transistor, an N-channel MOS (NMOS) input differential pair including an N-channel MOS transistor, and an output stage. The operational amplifier outputs an output voltage from the output stage according to two input voltages input to the PMOS input differential pair and the NMOS input differential pair.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram of an operational amplifier according to one embodiment of the present disclosure,

FIG. 2 is a schematic circuit diagram of an operational amplifier according to a reference technology,

FIG. 3 is a schematic circuit diagram of the operational amplifier according to one embodiment of the present disclosure,

FIG. 4 is a diagram illustrating a result of simulating frequency characteristics of the operational amplifier according to the present embodiment and the operational amplifier according to the reference technology,

FIG. 5 is a diagram illustrating a result of simulating frequency characteristics of the operational amplifier according to the present embodiment and the operational amplifier according to the reference technology,

FIG. 6 is a block diagram of an operational amplifier according to a second embodiment,

FIG. 7 is a circuit diagram of an input circuit and a current generation circuit according to the second embodiment,

FIG. 8 is a circuit diagram of the current generation circuit, a control circuit, and an output circuit according to the second embodiment,

FIG. 9 is a circuit diagram of a current generation circuit, a control circuit, and an output circuit according to a third embodiment;

FIG. 10 is a block diagram of a gain stage according to a fourth embodiment,

FIG. 11A is a circuit diagram of a first current generation circuit according to the fourth embodiment, and FIG. 11B is a circuit diagram of a second current generation circuit according to the fourth embodiment; and

FIG. 12 is a circuit diagram of a control circuit and an output circuit according to the fourth embodiment.

### DETAILED DESCRIPTION

### Overview

An overview of some exemplary embodiments of the present disclosure will be described. This summary describes some concepts of one or more embodiments in a simplified manner for the purpose of basic understanding of the embodiments as a prelude to the detailed description that follows and does not limit the breadth of the invention or disclosure. This summary is not a comprehensive overview of all possible embodiments and is not intended to identify key elements of all embodiments or delineate the scope of some or all aspects. For convenience, “one embodiment” may be used to refer to one embodiment (example or modification) or a plurality of embodiments (examples or modifications) disclosed in the present description.

An operational amplifier according to one embodiment includes: an input circuit including a PMOS input differential pair to which a first input voltage and a second input voltage are input and an NMOS input differential pair to which the first input voltage and the second input voltage are input, an operating input differential pair being switchable between the PMOS input differential pair and the NMOS input differential pair; a current generation circuit structured to generate a reference current; and an output circuit through which an idling current that increases according to an increase in the reference current flows, and structured to generate an output voltage according to output signals of the PMOS input differential pair and the NMOS input differential pair. The current generation circuit is structured to make the reference current larger in a case where a decreasing condition of the idling current is satisfied than in a case where the decreasing condition is not satisfied.

With this configuration, in a case where the idling current decreases, the reference current can be increased. Since the idling current increases according to the increase in the reference current, the idling current can be appropriately adjusted.

In one embodiment, the decreasing condition may be that a common voltage of the first input voltage and the second input voltage is higher than a predetermined voltage. Since the common voltage can be used together with other applications (switching of the input differential pair operating in the input circuit, and the like), the operational amplifier can be realized with a simpler configuration.

In one embodiment, the input circuit may be structured to switch the operating input differential pair according to a common voltage of the first input voltage and the second input voltage. The decreasing condition may be that the common voltage is a voltage at which the NMOS input differential pair operates. As a result, the operational amplifier can be realized with a simpler configuration.

In one embodiment, the input circuit may further include a tail current source structured to supply an electric current to operate the PMOS input differential pair and the NMOS input differential pair. The current generation circuit may include a reference current source structured to supply a first reference current, and may be structured to supply the first reference current as the reference current in a case where the PMOS input differential pair is operating, and to supply an electric current obtained by adding a second reference current to the first reference current as the reference current in a case where the NMOS input differential pair is operating. The second reference current may be an electric current obtained by copying the electric current supplied by the tail current source by a current mirror circuit.

In one embodiment, the output circuit may include a first output transistor including a P-channel MOS transistor and a second output transistor including an N-channel MOS transistor, the first output transistor and the second output transistor being push-pull connected. The current generation circuit may further include a first reference transistor including a P-channel MOS transistor and through which the reference current flows, and a second reference transistor including an N-channel MOS transistor and through which the reference current flows. The first output transistor, the second output transistor, the first reference transistor, and the second reference transistor may be provided to make a gate-source voltage of the first output transistor equal to a gate-source voltage of the first reference transistor, and to make a gate-source voltage of the second output transistor equal to a gate-source voltage of the second reference transistor.

A semiconductor device according to one embodiment includes the above operational amplifier.

With this configuration, in a case where the idling current decreases, the reference current can be increased. Since the idling current increases according to the increase in the reference current, the idling current can be appropriately adjusted.

### Embodiments

Hereinafter, preferred embodiments will be described with reference to the drawings. The same or equivalent constituent elements, members, and processes illustrated in the drawings are denoted by the same reference numerals, and redundant description will be omitted as appropriate. Furthermore, the embodiments are not intended to limit the disclosure and the invention, but are merely examples, and all features described in the embodiments and combinations thereof are not necessarily essential to the disclosure and the invention.

In the present description, “a state in which the member A is connected to the member B” includes not only a case where the member A and the member B are physically and directly connected to each other, but also a case where the member A and the member B are indirectly connected to each other via another member which does not substantially affect an electrical connection state between the member A and the member B or which does not impair a function or an effect exhibited by coupling between the member A and the member B.

Similarly, “a state in which the member C is connected (provided) between the member A and the member B” includes not only a case where the member A and the member C, or the member B and the member C are directly connected to each other, but also a case where the members are indirectly connected to each other via another member which does not substantially affect their electrical connection state or which does not impair a function or an effect exhibited by their coupling.

### First Embodiment

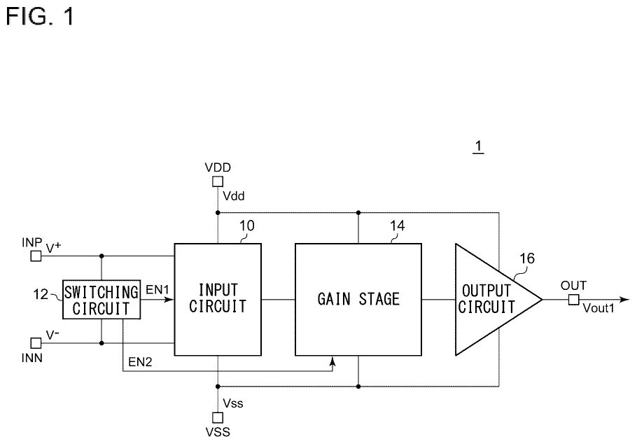

FIG. 1 is a block diagram of an operational amplifier 1 according to one embodiment of the present disclosure. The operational amplifier 1 amplifies a difference between a first input voltage V+ and a second input voltage V− to generate an output voltage Vout1. The operational amplifier 1 according to the present embodiment can be mounted on various semiconductor devices (for example, a semiconductor integrated circuit).

The operational amplifier 1 according to the present embodiment includes an input circuit 10, a switching circuit 12, a gain stage 14, an output circuit 16, a non-inverting input terminal INP, an inverting input terminal INN, a first power supply terminal VDD, a second power supply terminal VSS, and an output terminal OUT.

The first input voltage V+ is input to the non-inverting input terminal INP, and the second input voltage V− is input to the inverting input terminal INN. The first input voltage V+ and the second input voltage V− are supplied to the input circuit 10 and the switching circuit 12. An upper-side power supply voltage Vdd is input to the first power supply terminal VDD. A lower-side power supply voltage Vss (a ground voltage or the like) is input to the second power supply terminal VSS (for example, a ground terminal). The upper-side power supply voltage Vdd and the lower-side power supply voltage Vss are supplied to the input circuit 10, the gain stage 14, and the output circuit 16. The difference between the first input voltage V+ and the second input voltage V− is amplified through the input circuit 10, the gain stage 14, and the output circuit 16, and the output voltage Vout1 is output from the output terminal OUT.

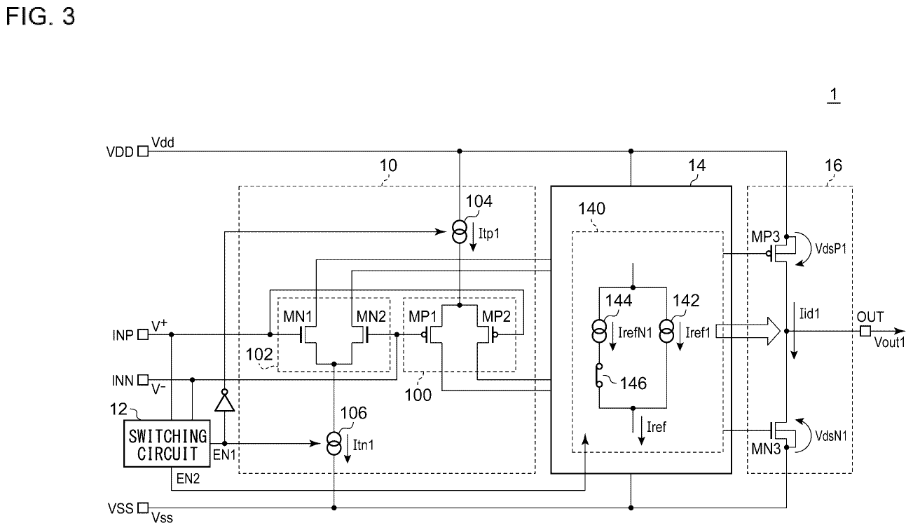

The switching circuit 12 detects a common voltage (hereinafter, also referred to as “input common voltage”) of the first input voltage V+ and the second input voltage V−. The switching circuit 12 according to the present embodiment generates enable signals EN1 and EN2 according to the detection result of the input common voltage and controls the operations of the input circuit 10 and the gain stage 14. The operation of the switching circuit 12 will be described in detail later with reference to FIG. 3.

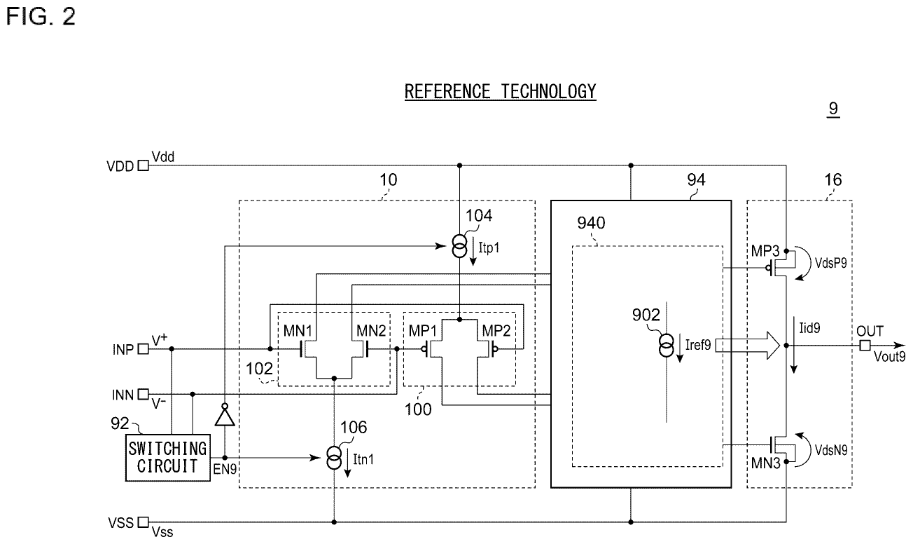

Before describing the operational amplifier 1 according to the present embodiment in detail, an operational amplifier according to a reference technology will be described. FIG. 2 is a schematic circuit diagram of an operational amplifier 9 according to the reference technology. The operational amplifier 9 according to the reference technology is obtained by replacing the switching circuit 12 and the gain stage 14 of the operational amplifier 1 according to the present embodiment with a switching circuit 92 and a gain stage 94 according to the reference technology, respectively. In FIG. 2, substantially the same components as those illustrated in FIG. 1 are denoted by the same reference numerals.

The input circuit 10 includes a PMOS input differential pair 100, an NMOS input differential pair 102, a first tail current source 104, and a second tail current source 106. The input circuit 10 is structured such that an operating input differential pair is switchable between the PMOS input differential pair 100 and the NMOS input differential pair 102.

The PMOS input differential pair 100 includes transistors MP1 and MP2 each including a P-channel MOS transistor. Sources of the transistors MP1 and MP2 are connected to each other, and a gate of the transistor MP2 is connected to the non-inverting input terminal INP. Drains of the transistors MP1 and MP2 are connected to the gain stage 94, and an output signal of the PMOS input differential pair 100 is input to the gain stage 94. The first tail current source 104 is supplied with the power supply voltage Vdd and is provided to be able to supply a tail current Itp1 to the sources of the transistors MP1 and MP2.

The NMOS input differential pair 102 includes transistors MN1 and MN2 each including an N-channel MOS transistor. Sources of the transistors MN1 and MN2 are connected to each other. Drains of the transistors MN1 and MN2 are connected to the gain stage 94, and an output signal of the NMOS input differential pair 102 is input to the gain stage 94. Agate of the transistor MN1 is connected to the non-inverting input terminal INP, and a gate of the transistor MN2 is connected to the inverting input terminal INN together with a gate of the transistor MP1. The second tail current source 106 is supplied with the lower-side power supply voltage Vss and is provided to be able to supply a tail current Itn1 to the sources of the transistors MN1 and MN2.

The switching circuit 92 is structured to switch the operating input differential pair between the PMOS input differential pair 100 and the NMOS input differential pair 102 according to the input common voltage of the first input voltage V+ and the second input voltage V−. The switching circuit 92 inputs a signal obtained by inverting an enable signal EN9 to the first tail current source 104 and inputs the enable signal EN9 to the second tail current source 106, thereby controlling on and off of the first tail current source 104 and the second tail current source 106.

For example, in a case where the input common voltage is equal to or less than a predetermined voltage, the switching circuit 92 generates the enable signal EN9 so as to turn on the first tail current source 104 and turn off the second tail current source 106. As a result, the first tail current source 104 supplies the tail current Itp1 to the PMOS input differential pair 100, and the PMOS input differential pair 100 operates. In a case where the input common voltage is higher than the predetermined voltage, the switching circuit 92 generates the enable signal EN9 so as to turn off the first tail current source 104 and turn on the second tail current source 106. As a result, the second tail current source 106 supplies the tail current Itn1 to the NMOS input differential pair 102, and the NMOS input differential pair 102 operates. As described above, the operating input differential pair is switched between the PMOS input differential pair 100 and the NMOS input differential pair 102 according to the input common voltage.

The gain stage 94 controls the operation of the output circuit 16 according to the output signals of the input circuit 10. The gain stage 94 is also structured to perform class-AB output control and control an idling current flowing through the output circuit 16. Specifically, the gain stage 94 generates a reference current Iref9 for an idling current Iid9 flowing through the output circuit 16. The function of generating the reference current Iref9 is realized by a current generation circuit 940 included in the gain stage 94. The current generation circuit 940 includes a reference current source 902, and the reference current source 902 generates the reference current Iref9.

The output circuit 16 generates an output voltage Vout9 according to the output signals of the PMOS input differential pair 100 and the NMOS input differential pair 102. The output voltage Vout9 swings around an output common voltage. The output circuit 16 includes a first output transistor MP3 including a P-channel MOS transistor and a second output transistor MN3 including an N-channel MOS transistor.

The first output transistor MP3 and the second output transistor MN3 are push-pull connected. Specifically, the first output transistor MP3 is provided such that its source is connected to the first power supply terminal VDD, its gate is connected to the current generation circuit 940, and its drain is connected to a drain of the second output transistor MN3. The second output transistor MN3 is provided such that its source is connected to the second power supply terminal VSS, its gate is connected to the current generation circuit 940, and its drain is connected to the output terminal OUT. The operations of the first output transistor MP3 and the second output transistor MN3 are controlled by the current generation circuit 940 in response to the output signals of the input circuit 10.

In a case where the output voltage Vout9 is higher than an upper-side threshold voltage, the first output transistor MP3 operates. In a case where the output voltage Vout9 is lower than a lower-side threshold voltage, the second output transistor MN3 operates. In a case where the output voltage Vout9 is equal to or less than the upper-side threshold voltage and equal to or more than the lower-side threshold voltage, the first output transistor MP3 and the second output transistor MN3 operate together.

The idling current Iid9 that increases according to an increase in the reference current Iref9 flows through the output circuit 16. Specifically, the idling current Iid9 flows through the first output transistor MP3 and the second output transistor MN3. The output circuit 16 and the gain stage 94 are structured such that an electric current that is N (N: a value larger than 1) times the reference current Iref9 flows through the first output transistor MP3 as the idling current Iid9 in a case where a source-drain voltage VdsP9 of the first output transistor MP3 is sufficiently high (saturated region). The output circuit 16 and the gain stage 94 are also structured such that an electric current that is N times the reference current Iref9 flows through the second output transistor MN3 as the idling current Iid9 in a case where a source-drain voltage VdsN9 of the second output transistor MN3 is sufficiently high (saturated region).

The higher the input common voltage, the higher the output common voltage. Particularly, when the NMOS input differential pair 102 is operating, the input common voltage and the output common voltage are higher and the source-drain voltage VdsP9 of the first output transistor MP3 is lower than when the PMOS input differential pair 100 is operating. At this time, the idling current Iid9 may be smaller than N times of the reference current Iref9 (Iid9<Iref9×N). Therefore, in the operational amplifier 9 according to the reference technology, in a case where the input common voltage is high enough to operate the NMOS input differential pair 102, the idling current Iid9 may not flow sufficiently, and the stability of the output voltage Vout9 may be lowered.

When the PMOS input differential pair 100 is operating, the output common voltage is lower than when the NMOS input differential pair 102 is operating. At this time, when the source-drain voltage VdsN9 of the second output transistor MN3 decreases according to a decrease in the output common voltage, the idling current Iid9 may become smaller than N times of the reference current Iref9. However, in general, the N-channel MOS transistor has a smaller influence on a drain current due to a decrease in a source-drain voltage than the P-channel MOS transistor. Therefore, the influence of a decrease in the output common voltage on the idling current Iid9 is smaller than the influence of an increase in the output common voltage on the idling current Iid9.

FIG. 3 is a schematic circuit diagram of the operational amplifier 1 according to the present embodiment. In FIG. 3, substantially the same components as those illustrated in FIG. 2 are denoted by the same reference numerals, and description thereof will be appropriately omitted.

The gain stage 14 according to the present embodiment controls the operation of the output circuit 16 according to the output signals of the input circuit 10. The gain stage 14 is also structured to perform class-AB output control and control an idling current Iid1 flowing through the output circuit 16. Specifically, the gain stage 14 generates a reference current Iref for the idling current Iid1 flowing through the output circuit 16. The function of generating the reference current Iref is realized by a current generation circuit 140 included in the gain stage 14.

The current generation circuit 140 generates the reference current Iref and is structured to make the reference current Iref larger in a case where a decreasing condition of the idling current Iid1 is satisfied than in a case where the decreasing condition of the idling current Iid1 is not satisfied. The decreasing condition of the idling current Iid1 is that the idling current Iid1 has decreased from a desired current (for example, a current that is N times the reference current Iref) to a certain extent (for example, to 90%, 80%, 70%, or the like of the desired current), or that parameters related to the idling current Iid1 have changed such that the idling current Iid1 decreases from the desired current to a certain extent. Examples of the parameters related to the idling current Iid1 include the input common voltage, the output common voltage, a source-drain voltage VdsP1 of the first output transistor MP3, and a source-drain voltage VdsN1 of the second output transistor MN3. In the present embodiment, the decreasing condition of the idling current Iid1 is that the input common voltage of the first input voltage V+ and the second input voltage V− is higher than the predetermined voltage. In the present embodiment, when this decreasing condition is satisfied, the NMOS input differential pair 102 operates.

The current generation circuit 140 according to the present embodiment includes a first reference current source 142, a second reference current source 144, and a switch 146. The first reference current source 142 and the second reference current source 144 are connected in parallel, and the second reference current source 144 and the switch 146 are connected in series. The current generation circuit 140 is structured such that a first reference current Iref1 supplied by the first reference current source 142 is the reference current Iref when the switch 146 is off (Iref=Iref1). The current generation circuit 140 is also structured such that a current obtained by adding a second reference current IrefN1 supplied by the second reference current source 144 to the first reference current Iref1 is the reference current Iref when the switch 146 is on (Iref=Iref1+IrefN1).

The switching circuit 12 can switch the input differential pair operating in the input circuit 10 using the enable signal EN1 in a similar manner to the switching circuit 92 according to the reference technology. The switching circuit 12 controls on and off of the switch 146 using the enable signal EN2.

The switching circuit 12 according to the present embodiment can control on and off of the switch 146 according to the input common voltage. Specifically, the switching circuit 12 turns off the switch 146 in a case where the input common voltage is a voltage at which the PMOS input differential pair 100 operates. The switching circuit 12 turns on the switch 146 in a case where the input common voltage is a voltage at which the NMOS input differential pair 102 operates.

The switching circuit 12 can switch on and off the switch 146 when switching the input differential pair operating in the input circuit 10. For example, in the case of switching the operating input differential pair from the PMOS input differential pair 100 to the NMOS input differential pair 102, the switching circuit 12 switches the switch 146 from off to on. In the case of switching the operating input differential pair from the NMOS input differential pair 102 to the PMOS input differential pair 100, the switching circuit 12 switches the switch 146 from on to off.

When the PMOS input differential pair 100 is operating, the reference current Iref of the current generation circuit 140 is Iref=Iref1. When the NMOS input differential pair 102 is operating, the reference current Iref is Iref=Iref1+IrefN1. When the NMOS input differential pair 102 is operating, the output common voltage is higher than when the PMOS input differential pair 100 is operating. Therefore, the source-drain voltage VdsP1 of the first output transistor MP3 may decrease, and the idling current Iid1 may become smaller than N times of the reference current Iref. However, the operational amplifier 1 according to the present embodiment can increase the idling current Iid1 by increasing the reference current Iref from Iref1 to Iref1+IrefN1. In this manner, the idling current Iid1 can be appropriately adjusted, and the output voltage Vout1 can be stabilized.

In a case where the PMOS input differential pair 100 operates after the switch 146 is turned on and the source-drain voltage of the first output transistor MP3 is sufficiently high, the reference current can be set to Iref1 by turning off the switch 146. This makes it possible to inhibit the reference current Iref and the idling current Iid1 from becoming unnecessarily large.

The configuration and operation of the operational amplifier 1 according to the present embodiment have been described above. In the operational amplifier 1 according to the present embodiment, the current generation circuit 140 is structured to make the reference current Iref larger in a case where the decreasing condition of the idling current Iid1 is satisfied than in a case where the decreasing condition of the idling current Iid1 is not satisfied. Therefore, in a case where the decreasing condition is satisfied, the idling current Iid1 can be appropriately adjusted by increasing the reference current Iref, and the output voltage Vout1 can be stabilized.

In addition, in the operational amplifier 1 according to the present embodiment, the decreasing condition is that the input common voltage is higher than the predetermined voltage. As a result, the common voltage can be used together with other applications (switching of the input differential pair operating in the input circuit, and the like), and the operational amplifier 1 can be realized with a simpler configuration.

Furthermore, the operational amplifier 1 according to the present embodiment is structured such that the operating input differential pair is switched according to the input common voltage, and the decreasing condition is that the common voltage is the voltage at which the NMOS input differential pair 102 operates. Therefore, the switching of the operating input differential pair and the switching of the reference current Iref can be simultaneously performed, and the operational amplifier 1 can be realized with a simpler configuration.

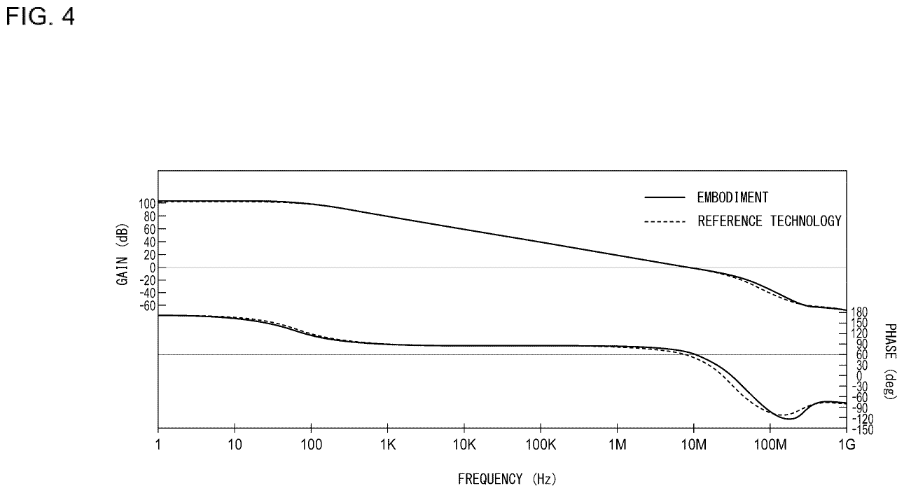

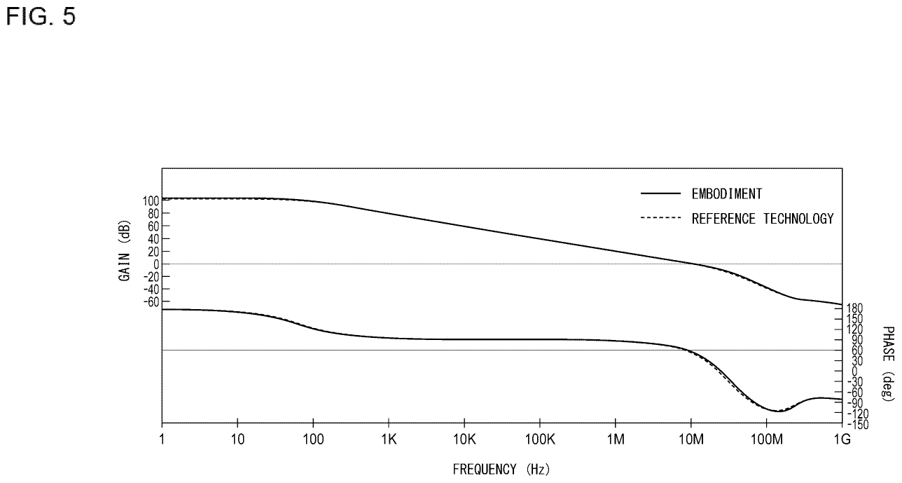

FIG. 4 and FIG. 5 are diagrams illustrating results of simulating frequency characteristics of the operational amplifier 1 according to the present embodiment and the operational amplifier 9 according to the reference technology.

The simulation result of the operational amplifier 9 according to the reference technology illustrated in FIG. 4 is a result obtained by setting the reference current Iref9 so that the idling current Iid9 is 604 μA when the PMOS input differential pair 100 is operating and the idling current Iid9 is 469 μA when the NMOS input differential pair 102 is operating. The simulation result of the operational amplifier 1 according to the present embodiment is a result obtained by setting the current generation circuit 140 so that the idling current Iid1 is 604 μA when the PMOS input differential pair 100 is operating and the idling current Iid1 is 1400 μA when the NMOS input differential pair 102 is operating. In FIG. 4, gain characteristics are illustrated on the upper side, and phase characteristics are illustrated on the lower side. The horizontal axis represents a frequency (Hz), and the vertical axis represents a gain (dB) and a phase (deg).

When the output impedance of the operational amplifier is denoted by ro and the idling current flowing through the output circuit of the operational amplifier is denoted by Ids, ro is proportional to the reciprocal of Ids. The output impedance ro decreases as the idling current Ids increases. As the output impedance ro decreases, a second pole frequency f_{2nd-pole} expressed by the following formula shifts to the high frequency side, and the phase margin of the operational amplifier is improved. Therefore, by increasing the idling current Ids, the phase margin of the operational amplifier can be improved.

f_{2nd-pole}=1/2πrₒCₒᵤₜ

In the simulation result of the operational amplifier 9 according to the reference technology, the unity gain frequency was 8.2 MHz, and the phase margin was 61.4 deg. On the other hand, in the simulation result of the operational amplifier 1 according to the present embodiment, the unity gain frequency was 8.6 MHz, and the phase margin was 69.3 deg. Therefore, it has been confirmed that the operational amplifier 1 according to the present embodiment can improve the gain characteristics and the phase margin.

The simulation result of the operational amplifier 9 according to the reference technology illustrated in FIG. 5 is a result obtained by setting the reference current similarly to the simulation result illustrated in FIG. 4. The simulation result of the operational amplifier 1 according to the present embodiment is a result obtained by setting the current generation circuit 140 so that the idling current Iid1 is 604 μA when the PMOS input differential pair 100 is operating and the idling current Iid1 is 665 μA when the NMOS input differential pair 102 is operating. In FIG. 5, gain characteristics are illustrated on the upper side, and phase characteristics are illustrated on the lower side. The horizontal axis represents a frequency (Hz), and the vertical axis represents a gain (dB) and a phase (deg).

In the simulation result of the operational amplifier 1 according to the present embodiment, the unity gain frequency was 8.3 MHz, and the phase margin was 64.5 deg. As described above, it has been confirmed that the gain characteristics and the phase margin can be improved also in a case where the current generation circuit 140 is set such that the idling current Iid1 is 665 μA when the NMOS input differential pair 102 is operating.

### Second Embodiment

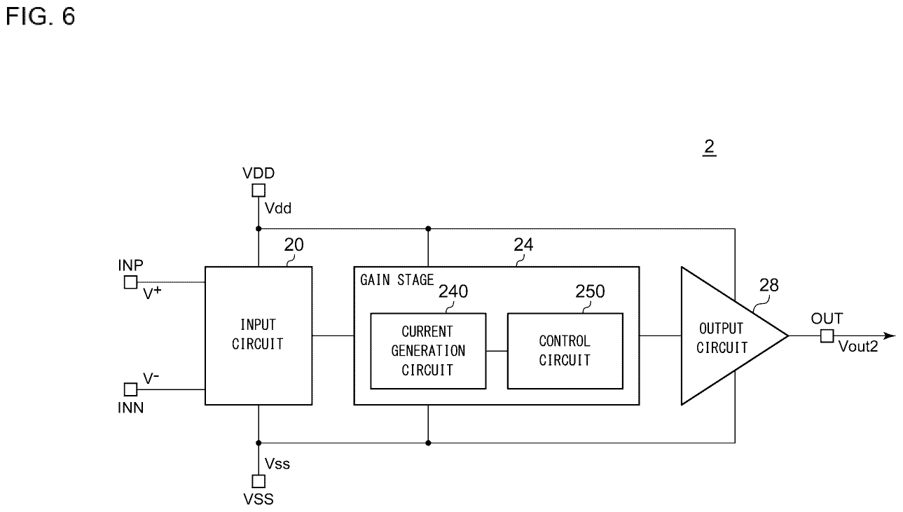

FIG. 6 is a block diagram of an operational amplifier 2 according to a second embodiment. In FIG. 6, substantially the same components as those illustrated in FIG. 1 are denoted by the same reference numerals, and description thereof will be appropriately omitted. The operational amplifier 2 according to the second embodiment includes an input circuit 20, a gain stage 24, an output circuit 28, the non-inverting input terminal INP, the inverting input terminal INN, the first power supply terminal VDD, the second power supply terminal VSS, and the output terminal OUT. The difference between the first input voltage V+ and the second input voltage V− is amplified through the input circuit 20, the gain stage 24, and the output circuit 28, and an output voltage Vout2 is output from the output terminal OUT.

The non-inverting input terminal INP and the inverting input terminal INN are connected to the input circuit 20. The first power supply terminal VDD and the second power supply terminal VSS are connected to the input circuit 20, the gain stage 24, and the output circuit 28. The output terminal OUT is connected to the output circuit 28.

The gain stage 24 according to the second embodiment controls the operation of the output circuit 28 according to output signals of the input circuit 20. The gain stage 24 is also structured to perform class-AB output control and control an idling current flowing through the output circuit 28. The gain stage 24 according to the second embodiment includes a current generation circuit 240 and a control circuit 250.

The current generation circuit 240 is structured to generate a reference current for the idling current flowing through the output circuit 28. The current generation circuit 240 is structured to make the reference current larger in a case where a decreasing condition of the idling current flowing through the output circuit 28 is satisfied than in a case where the decreasing condition of the idling current is not satisfied. In the present embodiment, the decreasing condition is that an input common voltage is a voltage at which an NMOS input differential pair 202 operates. The control circuit 250 is structured to control the idling current flowing through the output circuit 28 on the basis of the reference current generated by the current generation circuit 240.

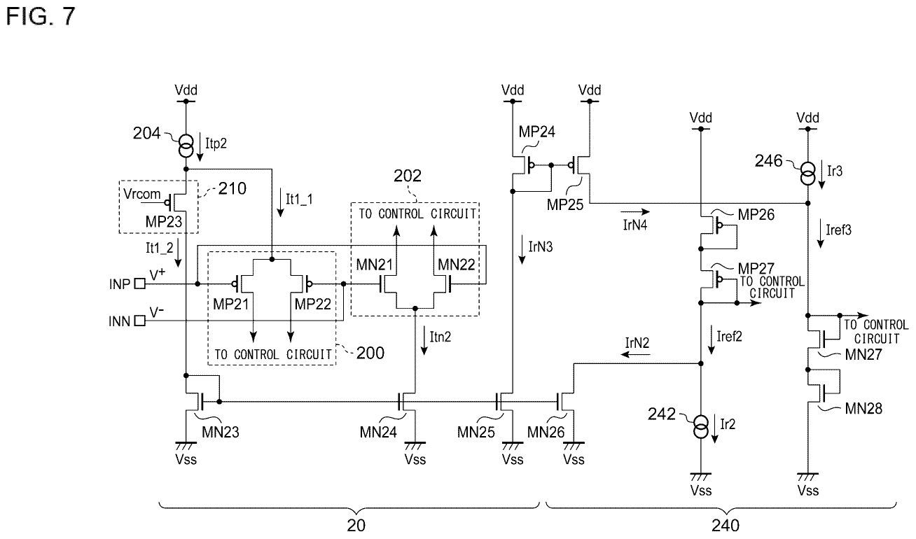

FIG. 7 is a circuit diagram of the input circuit 20 and the current generation circuit 240 according to the second embodiment. As illustrated in FIG. 7, the input circuit 20 includes a PMOS input differential pair 200, the NMOS input differential pair 202, a tail current source 204, transistors MP24 and MN23 to MN25, and a detection circuit 210. The input circuit 20 is structured such that an operating input differential pair is switchable between the PMOS input differential pair 200 and the NMOS input differential pair 202.

The PMOS input differential pair 200 includes transistors MP21 and MP22 each including a P-channel MOS transistor. A source of the transistor MP21 is connected to the tail current source 204 together with a source of the transistor MP22. A gate of the transistor MP21 is connected to the non-inverting input terminal INP. Drains of the transistors MP21 and MP22 are connected to the control circuit 250 as an output of the PMOS input differential pair 200. As a result, an output signal of the PMOS input differential pair 200 is output from a drain of the PMOS input differential pair 200 to the control circuit 250.

The tail current source 204 receives the upper-side power supply voltage Vdd and supplies a tail current Itp2. A current It1_1 corresponding to the tail current Itp2 supplied by the tail current source 204 flows to a source of the PMOS input differential pair 200.

The NMOS input differential pair 202 includes transistors MN21 and MN22 each including an N-channel MOS transistor. Sources of the transistors MN21 and MN22 are connected to each other and drains of the transistors MN21 and MN22 are connected to the control circuit 250 as an output of the NMOS input differential pair 202. As a result, an output signal of the NMOS input differential pair 202 is output from a drain of the NMOS input differential pair 202 to the control circuit 250. Agate of the transistor MN22 is connected to the non-inverting input terminal INP, and a gate of the transistor MN21 is connected to the inverting input terminal INN together with a gate of the transistor MP22.

Each of the transistors MN23 to MN25 includes an N-channel MOS transistor. The transistors MN23 to MN25 and a transistor MN26 to be described later constitute a current mirror circuit. Specifically, the transistor MN23 forms a current mirror pair with each of the transistors MN24 to MN26.

The lower-side power supply voltage Vss is supplied to sources of the transistors MN23 to MN25. Agate of the transistor MN23 is connected to a drain of the transistor MN23 together with gates of the transistors MN24 and MN25. A drain of the transistor MN24 is connected to the sources of the transistors MN21 and MN22.

The transistor MP24 includes a P-channel MOS transistor. The transistor MP24 and a transistor MP25 to be described later constitute a current mirror circuit. The upper-side power supply voltage Vdd is supplied to a source of the transistor MP24. A gate of the transistor MP24 is connected to a drain of the transistor MN25 together with a drain of the transistor MP24.

The detection circuit 210 is a circuit for detecting the input common voltage of the first input voltage V+ and the second input voltage V−. The detection circuit 210 includes a transistor MP23 including a P-channel MOS transistor. The transistor MP23 is provided such that a bias voltage Vrcom is supplied to its gate, its source is connected to the tail current source 204, and its drain is connected to the drain of the transistor MN23. A current It1_2 corresponding to the tail current Itp2 supplied by the tail current source 204 flows through the transistor MP23.

The current generation circuit 240 includes transistors MP25 to MP27 and MN26 to MP28, a first reference current source 242, and a second reference current source 246. The current generation circuit 240 is structured such that the reference current is a first reference current Ir2 and a first reference current Ir3 respectively supplied by the first reference current source 242 and the second reference current source 246 in a case where the input common voltage is a voltage at which the PMOS input differential pair 200 operates, and the reference current is a current obtained by adding a second reference current to the first reference current in a case where the input common voltage is a voltage at which the NMOS input differential pair 202 operates. The second reference current is a current obtained by copying the current supplied by the tail current source 204 by the current mirror circuit.

Each of the transistors MP25 to MP27 includes a P-channel MOS transistor. The transistor MP25 is provided such that the upper-side power supply voltage Vdd is supplied to its source, and its gate is connected to the gate of the transistor MP24. The transistor MP26 is a first reference transistor and is provided such that the upper-side power supply voltage Vdd is supplied to its source and its gate is connected to its drain. The transistor MP27 is provided such that its source is connected to the drain of the transistor MP26 and its gate is connected to the first reference current source 242 and the control circuit 250 together with its drain. A reference current Iref2 (drain current) flows through the transistors MP26 and MP27. The reference current Iref2 is used for the idling current of the output circuit 28 and is the sum of the first reference current Ir2 supplied by the first reference current source 242 and a second reference current IrN2 flowing through the transistor MN26 (Iref2=Ir2+IrN2).

Each of the transistors MN26 to MN28 includes an N-channel MOS transistor. The transistor M1N26 is provided such that the lower-side power supply voltage Vss is supplied to its source, its gate is connected to the gate of the transistor MN23, and its drain is connected to the drain of the transistor MP27. The transistor MN28 is a second reference transistor and is provided such that the lower-side power supply voltage Vss is supplied to its source and its gate is connected to its drain. The transistor MN27 is provided such that its source is connected to the drain of the transistor MN28 and its gate is connected to a drain of the transistor MP25, the second reference current source 246, and the control circuit 250 together with its drain. A reference current Iref3 flows through the transistors MN27 and MN28. The reference current Iref3 is used for the idling current of the output circuit 28 and is the sum of the first reference current Ir3 supplied by the second reference current source 246 and a second reference current IrN4 flowing through the transistor MP25 (Iref3=Ir3+IrN4). Here, the first reference current Ir3 is equal to the first reference current Ir2 (Ir3=Ir2).

The configurations of the input circuit 20 and the current generation circuit 240 have been described above. Here, the operations of the input circuit 20 and the current generation circuit 240 will be described.

In a case where the input common voltage is sufficiently lower than the bias voltage Vrcom, all the tail current Itp2 flows to the PMOS input differential pair 200 (It1_1=Itp2), and the current It1_2 does not flow to the transistor MP23 (It1_2=0). At this time, the PMOS input differential pair 200 operates. When the PMOS input differential pair 200 is operating, the second reference current IrN2 does not flow through the transistor MN26 (IrN2=0). Therefore, the reference current Iref2 is equal to the first reference current Ir2 supplied by the first reference current source 242 (Iref2=Ir2). Since no current IrN3 flows through the transistor MP24, the second reference current IrN4 does not flow through the transistor MP25. Therefore, the reference current Iref3 is equal to the first reference current Ir3 supplied by the second reference current source 246 (Iref3=Ir3).

When the input common voltage increases to approximately the bias voltage Vrcom, the current It1_2 starts flowing through the transistor MP23. The current It1_2 is copied by the current mirror circuit, and a current Itn2 is supplied to the drain of the NMOS input differential pair 202. As the input common voltage approaches the upper-side power supply voltage Vdd, the current Itn2 supplied to the NMOS input differential pair 202 increases. In this manner, the operating input differential pair is switched from the PMOS input differential pair 200 to the NMOS input differential pair 202.

When the NMOS input differential pair 202 is operating, the second reference current IrN2 obtained by copying the current It1_2 supplied by the tail current source 204 flows through the transistor MN26. Therefore, the reference current Iref2 is a current obtained by adding the second reference current IrN2 to the first reference current Ir2 (Iref2=Ir2+IrN2). The current IrN3 obtained by copying the current It1_2 flows through the transistor MP24. Furthermore, the second reference current IrN4 obtained by copying the current IrN3 flows through the transistor MP25. Therefore, the reference current Iref3 is a current obtained by adding the second reference current IrN4 to the first reference current Ir3 (Iref3=Ir3+IrN4). Here, the second reference current IrN4 is substantially equal to the second reference current IrN2. In this manner, the input differential pair operating according to a change in the input common voltage is switched between the PMOS input differential pair 200 and the NMOS input differential pair 202, and the magnitudes of the reference currents Iref2 and Iref3 are switched.

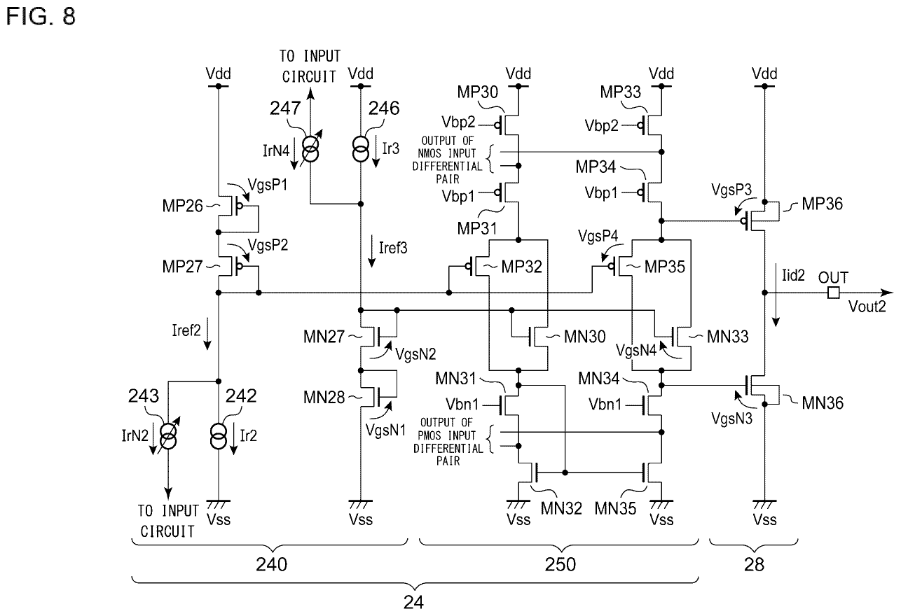

FIG. 8 is a circuit diagram of the current generation circuit 240, the control circuit 250, and the output circuit 28 according to the second embodiment. Since the second reference current IrN2 is switched according to the operation of the transistor MN26, the transistor MN26 is replaced with a first variable current source 243 in FIG. 8. Since the second reference current IrN4 is switched according to the operation of the transistor MP25, the transistor MP25 is replaced with a second variable current source 247 in FIG. 8.

The control circuit 250 includes transistors MP30 to MP35 and MN30 to MN35. Each of the transistors MP30 to MP35 includes a P-channel MOS transistor. Each of the transistors MN30 to MN35 includes an N-channel MOS transistor.

The transistor MP30 is provided such that the upper-side power supply voltage Vdd is supplied to its source, and its drain is connected to a source of the transistor MP31. The transistor MP33 is provided such that the upper-side power supply voltage Vdd is supplied to its source, and its drain is connected to a source of the transistor MP34. A bias voltage Vbp2 is supplied to gates of the transistors MP30 and MP33.

The transistor MP31 is provided such that its drain is connected to a source of the transistor MP32 and a drain of the transistor MN30. A drain of the transistor MP34 is connected to a source of the transistor MP35 and a drain of the transistor MN33. A bias voltage Vbp1 is supplied to gates of the transistors MP31 and MP34. An output (specifically, the drain of the transistor MN21) of the NMOS input differential pair 202 is connected between the transistor MP30 and the transistor MP31. An output (specifically, the drain of the transistor MN22) of the NMOS input differential pair 202 is connected between the transistor MP33 and the transistor MP34.

The transistor MP32 is provided such that its gate is connected to the gate of the transistor MP27 and its drain is connected to a drain of the transistor MN31. The transistor MN30 is provided such that its gate is connected to the gate of the transistor MN27 and its source is connected to the drain of the transistor MN31.

The transistor MP35 is provided such that its gate is connected to the gate of the transistor MP27 and its drain is connected to a drain of the transistor MN34. The transistor MN33 is provided such that its gate is connected to the gate of the transistor MN27 and its drain is connected to the drain of the transistor MN34.

The transistor MN31 is provided such that its source is connected to a drain of the transistor MN32. The transistor MN34 is provided such that its source is connected to a drain of the transistor MN35. A bias voltage Vbn1 is supplied to gates of the transistors MN31 and MN34.

The transistors MN32 and MN35 constitute a current mirror circuit. The transistor MN32 is provided such that the lower-side power supply voltage Vss is supplied to its source, and its gate is connected to the drain of the transistor MN31. The transistor MN35 is provided such that the lower-side power supply voltage Vss is supplied to its source, and its gate is connected to the gate of the transistor MN32. An output (specifically, the drain of the transistor MP22) of the PMOS input differential pair 200 is connected between the transistor MN31 and the transistor MN32. An output (specifically, the drain of the transistor MP21) of the PMOS input differential pair 200 is connected between the transistor MN34 and the transistor MN35.

The output circuit 28 generates the output voltage Vout2 according to the output signals of the NMOS input differential pair 202 and the PMOS input differential pair 200. An idling current Iid2 that increases according to an increase in the reference currents Iref2 and Iref3 generated by the current generation circuit 240 flows through the output circuit 28. The output circuit 28 according to the second embodiment is structured similarly to the output circuit 16 according to the first embodiment. The output circuit 28 includes a first output transistor MP36 including a P-channel MOS transistor and a second output transistor MN36 including an N-channel MOS transistor.

The first output transistor MP36 is provided such that the upper-side power supply voltage Vdd is supplied to its source, its gate is connected to the drain of the transistor MP34, and its drain is connected to a drain of the second output transistor MN36. The second output transistor MN36 is provided such that the lower-side power supply voltage Vss is supplied to its source, and its gate is connected to the drain of the transistor MN34. The output terminal OUT is connected between the first output transistor MP36 and the second output transistor MN36.

Gate voltages of the transistors MP27 and MP35 are common. Therefore, when a gate-source voltage of the transistor MP26 is VgsP1, a gate-source voltage of the transistor MP27 is VgsP2, a gate-source voltage of the first output transistor MP36 is VgsP3, and a gate-source voltage of the transistor MP35 is VgsP4, the following equation holds.

VgsP1+VgsP2=VgsP3+VgsP4 (1)

In the present embodiment, the sizes of the transistors MP26, MP27, MP35 and the first output transistor MP36 are designed so as to satisfy the following equations.

$$VgsP 1 = VgsP 3 , VgsP 2 = VgsP 4 \qquad ( 2 )$$

Gate voltages of the transistors MN27 and MN33 are common. Therefore, when a gate-source voltage of the transistor MN28 is VgsN1, a gate-source voltage of the transistor MN27 is VgsN2, a gate-source voltage of the second output transistor MN36 is VgsN3, and a gate-source voltage of the transistor MN33 is VgsN4, the following equation holds.

$$VgsN 1 + VgsN 2 = VgsN 3 + VgsN 4 \qquad ( 3 )$$

In the present embodiment,
the sizes of the transistors MN27, MN28, MN33 and the second output transistor MN36 are designed so as to satisfy the following equations.

$$VgsN 1 = VgsN 3 , VgsN 2 = VgsN 4 \qquad ( 4 )$$

A drain current (saturation current) Ids of the MOS transistor is given by the following equations.

$$\begin{matrix}Ids = ( β / 2 ) \times {( Vgs - Vt )}^{2} \\ β = ( W / L ) \times μ Cox\end{matrix}$$

Here, Vgs is a gate-source voltage, Vt is a threshold voltage, W is a channel width, L is a channel length, μ is carrier mobility, and Cox is a unit capacitance of a gate oxide film.

For the reference current Iref2 and the idling current Iid2, Equations (5) and (6) described below hold by combining the types and W/L of the transistor MP26 and the first output transistor MP36.

$$Iref 2 = Np\_ref 1 \times [ ( W / L ) \times ( μ Cox / 2 ) \times {( Vgs - Vt )}^{2} ] \qquad ( 5 )$$

$$Iid 2 = Np\_out 1 \times [ ( W / L ) \times ( μ Cox / 2 ) \times {( Vgs - Vt )}^{2} ] \qquad ( 6 )$$

Np_ref1 is a predetermined coefficient (integer) corresponding to the size of the transistor MP26, and Np_out1 is a predetermined coefficient (integer) corresponding to the size of the output transistor MP36.

A relationship between the reference current Iref2 and the idling current Iid2 can be set by a ratio of coefficients Np_ref1 and Np_out1 by canceling elements other than these coefficients as in the following equation.

$$\begin{matrix}Iref 2 : Iid 2 = Np\_ref 1 : Np\_out 1 \\ Iid 2 \times Np\_ref 1 = Iref 2 \times Np\_out 1\end{matrix} \qquad ( 7 )$$

The sizes of the transistor MP27 and the transistor MP35 are designed such that VgsP2=VgsP4 as expressed by Equation (2) described above. Specifically, the sizes of the transistor MP27 and the transistor MP35 are designed according to the magnitudes of currents flowing through the transistors MP27 and MP35. For example, in a case where an equal current (Iref2) flows through the transistors MP27 and MP35, these transistors are designed with the same W/L. In a case where different currents flow through these transistors, these transistors are designed with different W/L.

For the reference current Iref3 and the idling current Iid2, Equations (8) and (9) described below hold by combining the types and W/L of the transistor MN28 and the second output transistor MN36.

$$Iref 3 = Nn\_ref 1 \times [ ( W / L ) \times ( μ Cox / 2 ) \times {( Vgs - Vt )}^{2} ] \qquad ( 8 )$$

$$Iid 2 = Nn\_out 1 \times [ ( W / L ) \times ( μ Cox / 2 ) \times {( Vgs - Vt )}^{2} ] \qquad ( 9 )$$

Nn_ref1 is a predetermined coefficient (integer) corresponding to the size of the transistor MN28, and Nn_out1 is a predetermined coefficient (integer) corresponding to the size of the output transistor MN36.

A relationship between the reference current Iref3 and the idling current Iid2 can be set by a ratio of coefficients Nn_ref1 and Nn_out1 by canceling elements other than these coefficients as in the following equation.

$$\begin{matrix}Iref 3 : Iid 2 = Nn\_ref 1 : Nn\_out 1 \\ Iid 2 \times Nn\_ref 1 = Iref 3 \times Nn\_out 1\end{matrix} \qquad ( 10 )$$

The sizes of the transistor MN27 and the transistor MN33 are designed such that VgsN2=VgsN4 as expressed by Equation (4) described above. Specifically, the sizes of the transistor MN27 and the transistor MN33 are designed according to the magnitudes of currents flowing through the transistors MN27 and MN33. For example, in a case where an equal current (Iref3) flows through the transistors MN27 and MN33, these transistors are designed with the same W/L. In a case where different currents flow through these transistors, these transistors are designed with different W/L.

From Equations (7) and (10), the following equation holds.

$$\begin{matrix}Iid 2 = Iref 2 \times ( Np\_out 1 / Np\_ref 1 ) \\ = Iref 3 \times ( Nn\_out 1 / Nn\_ref 1 )\end{matrix} \qquad ( 11 )$$

Here, the reference current Iref2 is substantially equal to the reference current Iref3. The transistors MP26 and MN28, the first output transistor MP36, and the second output transistor MN36 are structured such that Np_out1/Np_ref1 is equal to Nn_out1/Nn_ref1. According to Equation (11), the idling current Iid2 can be appropriately adjusted by controlling the reference currents Iref2 and Iref3.

In the operational amplifier 2 according to the present embodiment, the current generation circuit 240 increases the reference currents Iref2 and Iref3 in a case where the decreasing condition of the idling current Iid2 is satisfied than in a case where the decreasing condition of the idling current Iid2 is not satisfied. In a case where the input common voltage is the voltage at which the NMOS input differential pair 202 operates, the reference currents Iref2 and Iref3 are larger than in a case where the input common voltage is not the voltage at which the NMOS input differential pair 202 operates (that is, in a case where the input common voltage is the voltage at which the PMOS input differential pair 200 operates). Specifically, when the PMOS input differential pair 200 is operating, the reference currents Iref2 and Iref3 are the first reference currents Ir2 and Ir3. When the operating input differential pair is switched from the PMOS input differential pair 200 to the NMOS input differential pair 202, the second reference currents IrN2 and IrN4 are added to the reference currents Iref2 and Iref3. As a result, the reference currents Iref2 and Iref3 increase, the idling current Iid2 can be appropriately adjusted, and the output voltage Vout2 can be stabilized.

### Third Embodiment

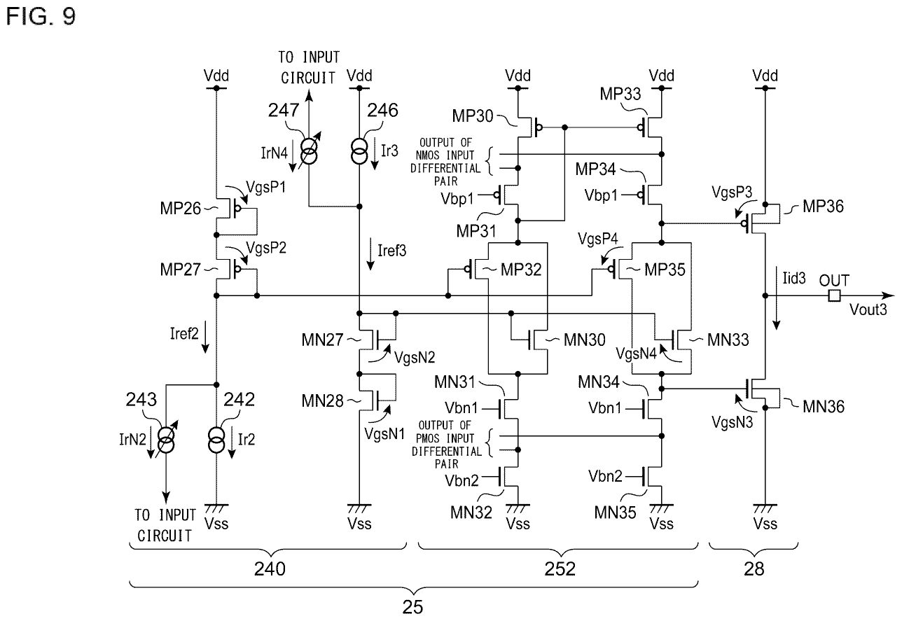

A third embodiment is different from the second embodiment in the configuration of a control circuit included in a gain stage. An operational amplifier according to the third embodiment has a configuration in which the control circuit in the operational amplifier according to the second embodiment is replaced with a control circuit according to the third embodiment. FIG. 9 is a circuit diagram of the current generation circuit 240, a control circuit 252, and the output circuit 28 according to the third embodiment. In FIG. 9, substantially the same components as those illustrated in FIG. 8 are denoted by the same reference numerals, and description thereof will be appropriately omitted.

Again stage 25 according to the third embodiment includes the current generation circuit 240 and the control circuit 252. The control circuit 252 according to the third embodiment is different from the second embodiment mainly in the gate connection of the transistors MP30, MP33, MN32, and MN35.

The transistors MP30 and MP33 constitute a current mirror circuit. The gate of the transistor MP30 is connected to the drain of the transistor MP31. The gate of the transistor MP33 is connected to the gate of the transistor MP30. A bias voltage Vbn2 is supplied to the gates of the transistors MN32 and MN35.

In a case where the control circuit 252 is structured as in the third embodiment, an idling current Iid3 flowing through the output circuit 28 is expressed by the following equation similarly to the second embodiment.

$$\begin{matrix}Iid 3 = Iref 2 \times ( Np\_out 1 / Np\_ref 1 ) \\ = Iref 3 \times ( Nn\_out 1 / Nn\_ref 1 )\end{matrix} \qquad ( 12 )$$

By controlling the reference currents Iref2 and Iref3, the idling current Iid3 can be appropriately adjusted, and an output voltage Vout3 can be stabilized.

### Fourth Embodiment

A fourth embodiment is different from the second embodiment mainly in the configuration of a gain stage. An operational amplifier according to the fourth embodiment may have a configuration in which the gain stage 24 in the operational amplifier 2 according to the second embodiment is replaced with a gain stage according to the fourth embodiment.

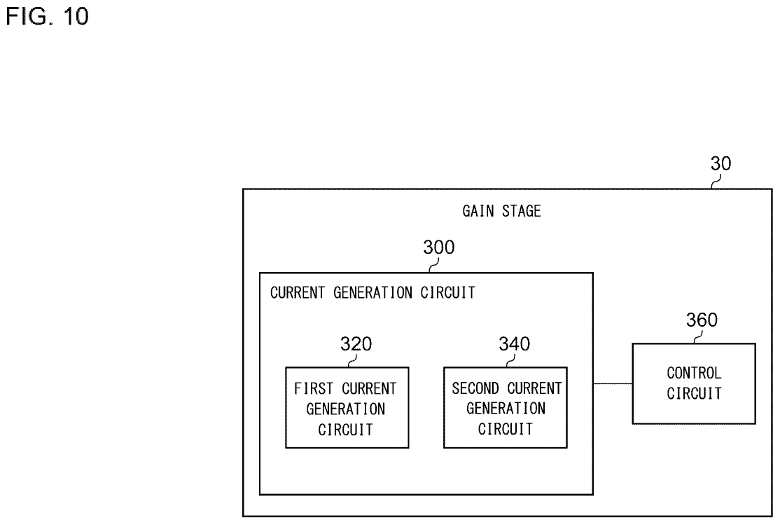

FIG. 10 is a block diagram of a gain stage 30 according to the fourth embodiment. The gain stage 30 according to the fourth embodiment includes a current generation circuit 300 and a control circuit 360. The current generation circuit 300 according to the present embodiment is structured to generate a reference current and includes a first current generation circuit 320 and a second current generation circuit 340. The control circuit 360 is structured to control an idling current flowing through the output circuit 28 on the basis of the reference current generated by the current generation circuit 300.

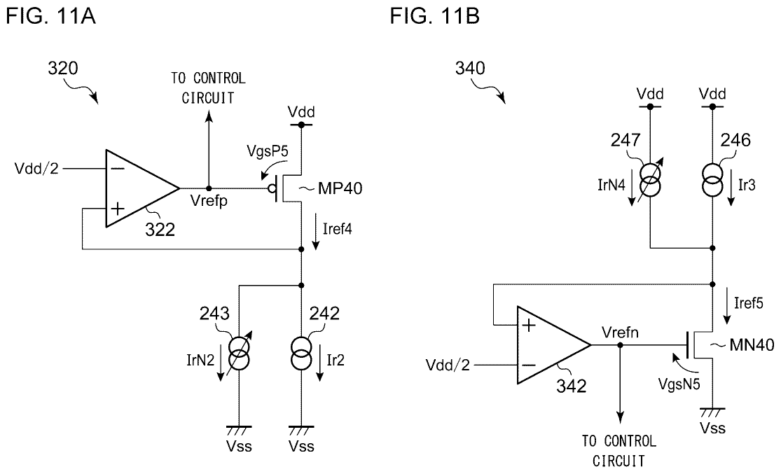

FIG. 11A is a circuit diagram of the first current generation circuit 320, and FIG. 11B is a circuit diagram of the second current generation circuit 340. In FIG. 11A and FIG. 11B, substantially the same components as those illustrated in FIG. 8 are denoted by the same reference numerals, and description thereof will be appropriately omitted.

As illustrated in FIG. 11A, the first current generation circuit 320 includes the first reference current source 242, the first variable current source 243, a transistor MP40, and an amplifier 322. The first reference current source 242 and the first variable current source 243 are structured similarly to the first reference current source 242 and the first variable current source 243 according to the second embodiment.

The transistor MP40 is a first reference transistor and includes a P-channel MOS transistor. The transistor MP40 is provided such that the upper-side power supply voltage Vdd is supplied to its source, its gate is connected to an output terminal of the amplifier 322, and its drain is connected to the first reference current source 242 and the first variable current source 243. The amplifier 322 is provided such that a voltage (Vdd/2) that is half the upper-side power supply voltage Vdd is supplied to its inverting input terminal, its non-inverting input terminal is connected to the drain of the transistor MP40, and its output terminal is connected to the control circuit 360.

A reference current Iref4 flows through the transistor MP40. The reference current Iref4 is the sum of the first reference current Ir2 supplied by the first reference current source 242 and the second reference current IrN2 supplied by the first variable current source 243 (Iref4=Ir2+IrN2).

When a gate-source voltage of the transistor MP40 is VgsP5, an output voltage Vrefp of the amplifier 322 is expressed by Vrefp=Vdd−VgsP5.

As illustrated in FIG. 11B, the second current generation circuit 340 includes the second reference current source 246, the second variable current source 247, a transistor MN40, and an amplifier 342. The second reference current source 246 and the second variable current source 247 are structured similarly to the second reference current source 246 and the second variable current source 247 according to the second embodiment.

The transistor MN40 is a second reference transistor and includes an N-channel MOS transistor. The transistor MN40 is provided such that the lower-side power supply voltage Vss is supplied to its source, its gate is connected to an output terminal of the amplifier 342, and its drain is connected to the second reference current source 246 and the second variable current source 247. The amplifier 342 is provided such that a voltage (Vdd/2) that is half the upper-side power supply voltage Vdd is supplied to its inverting input terminal, its non-inverting input terminal is connected to the drain of the transistor MN40, and its output terminal is connected to the control circuit 360.

A reference current Iref5 flows through the transistor MN40. The reference current Iref5 is the sum of the first reference current Ir3 supplied by the second reference current source 246 and the second reference current IrN4 supplied by the second variable current source 247 (Iref5=Ir3+IrN4).

When a gate-source voltage of the transistor MN40 is VgsN5, an output voltage Vrefn of the amplifier 342 is expressed by

$$Vrefn = Vss - VgsN 5.$$

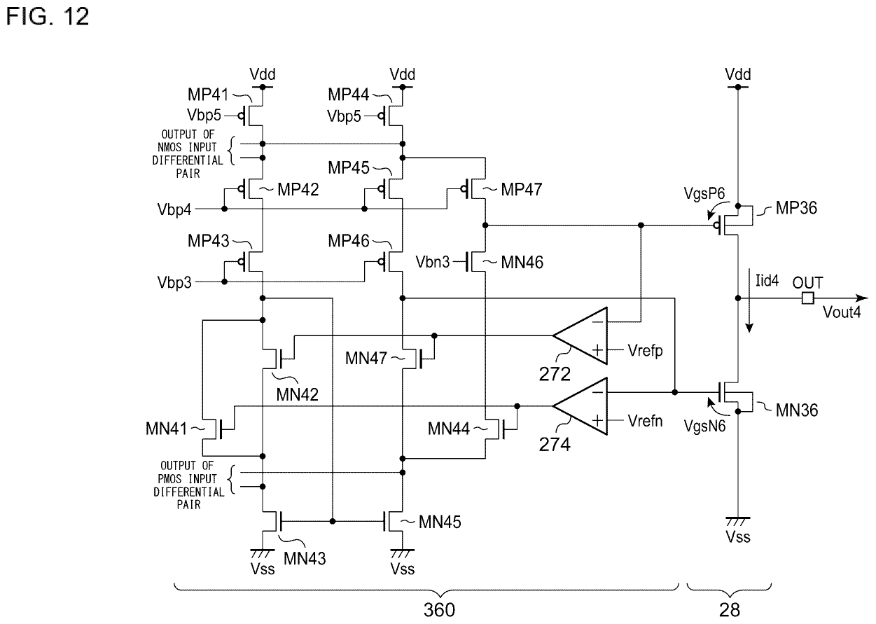

FIG. 12 is a circuit diagram of the control circuit 360 and the output circuit 28 according to the fourth embodiment. The output circuit 28 according to the fourth embodiment has substantially the same configuration as the output circuit 28 according to the second embodiment.

The control circuit 360 according to the fourth embodiment includes transistors MP41 to MP47, MN41 to MN47, and amplifiers 272 and 274. Each of the transistors MP41 to MP47 includes a P-channel MOS transistor. Each of the transistors MN41 to MN47 includes an N-channel MOS transistor.

The transistor MP41 is provided such that the upper-side power supply voltage Vdd is supplied to its source, and its drain is connected to a source of the transistor MP42. The transistor MP44 is provided such that the upper-side power supply voltage Vdd is supplied to its source, and its drain is connected to sources of the transistor MP45 and the transistor MP47. A bias voltage Vbp5 is supplied to gates of the transistors MP41 and MP44. An output (specifically, the drain of the transistor MN21) of the NMOS input differential pair 202 is connected between the transistor MP41 and the transistor MP42.

A drain of the transistor MP42 is connected to a source of the transistor MP43. A drain of the transistor MP45 is connected to a source of the transistor MP46. A drain of the transistor MP47 is connected to a drain of the transistor MN46 and the gate of the first output transistor MP36. An output (specifically, the drain of the transistor MN22) of the NMOS input differential pair 202 is connected between the transistor MP44 and the transistor MP45. A bias voltage Vbp4 is supplied to gates of the transistors MP42, MP45, and MP47.

A drain of the transistor MP43 is connected to the transistors MN41 and MN42. A drain of the transistor MP46 is connected to a drain of the transistor MN47 and the gate of the second output transistor MN36. A source of the transistor MN46 is connected to a drain of the transistor MN44. A bias voltage Vbp3 is supplied to gates of the transistors MP43 and MP46, and a bias voltage Vbn3 is supplied to a gate of the transistor MN46.

The transistors MN43 and MN45 constitute a current mirror circuit. The transistor MN43 is provided such that the lower-side power supply voltage Vss is supplied to its source, its gate is connected to the drain of the transistor MP43 together with a gate of the transistor MN45, and its drain is connected to drains of the transistors MN41 and MN42. The transistor MN45 is provided such that the lower-side power supply voltage Vss is supplied to its source, and its drain is connected to sources of the transistors MN44 and MN47. An output (specifically, the drain of the transistor MP22) of the PMOS input differential pair 200 is connected between the transistor MN43 and the transistors MN41 and MN42. An output (specifically, the drain of the transistor MP21) of the PMOS input differential pair 200 is connected between the transistor MN45 and the transistors MN44 and MN47.

The amplifier 272 is provided such that its inverting input terminal is connected to the gate of the first output transistor MP36, the output voltage Vrefp of the amplifier 322 included in the first current generation circuit 320 is supplied to its non-inverting input terminal, and its output terminal is connected to gates of the transistors MN42 and MN47.

The amplifier 274 is provided such that its inverting input terminal is connected to the gate of the second output transistor MN36, the output voltage Vrefn of the amplifier 342 included in the second current generation circuit 340 is supplied to its non-inverting input terminal, and its output terminal is connected to gates of the transistors MN41 and MN44.

In the gain stage 30 and the output circuit 28 according to the present embodiment, the gate-source voltage VgsP5 of the transistor MP40 included in the first current generation circuit 320 is equal to a gate-source voltage VgsP6 of the first output transistor MP36 included in the output circuit 28 (VgsP5=VgsP6). The gate-source voltage VgsN5 of the transistor MN40 included in the second current generation circuit 340 is equal to a gate-source voltage VgsN6 of the second output transistor MN36 included in the output circuit 28 (VgsN5=VgsN6).

Coefficients (integers) corresponding to the sizes of the transistor MP40 and the first output transistor MP36 are Np_ref2 and Np_out2, respectively. Coefficients (integers) corresponding to the sizes of the transistor MN40 and the second output transistor MN36 are Nn_ref2 and Nn_out2, respectively. Similarly to the second embodiment, an idling current Iid4 can be set by a size ratio of the transistor MP40 and the first output transistor MP36 or a size ratio of the transistor MN40 and the second output transistor MN36. The idling current Iid4 flowing through the output circuit 28 is expressed by the following equation.

$$\begin{matrix}Iid 4 = Iref 4 \times ( Np\_out 2 / Np\_ref 2 ) \\ = Iref 5 \times ( Nn\_out 2 / Nn\_ref 2 )\end{matrix} \qquad ( 13 )$$

In Equation (13), the reference current Iref4 is substantially equal to the reference current Iref5. In addition, Np_out2/Np_ref2 is equal to Nn_out2/Nn_ref2.

According to the fourth embodiment, by controlling the reference currents Iref4 and Iref5, the idling current Iid4 can be appropriately adjusted, and an output voltage Vout4 can be stabilized.

### Modifications

In the above embodiments, an example has been mainly described in which the reference current is controlled depending on whether the operating input differential pair is the PMOS input differential pair or the NMOS input differential pair. The present disclosure is not limited to this example, and the reference current may be controlled regardless of the operating input differential pair. For example, the input common voltage, the output common voltage, the source-drain voltage of the first output transistor, the idling current, and the like may be detected, and the reference current may be controlled on the basis of the detection results.

For example, in a case where the output common voltage is higher than a predetermined voltage, the reference current may be made higher than in a case where the output common voltage is less than the predetermined voltage. In addition, in a case where the source-drain voltage of the first output transistor is lower than a predetermined voltage, the reference current may be made higher than in a case where the source-drain voltage is equal to or more than the predetermined voltage. Furthermore, in a case where the idling current is lower than a predetermined current, the reference current may be made higher than in a case where the idling current is equal to or more than the predetermined current. As a result, a decrease in the idling current can be inhibited, and the output voltage can be stabilized.

In the above embodiments, an example has been mainly described in which the reference current is controlled in two stages. The present disclosure is not limited to this example, and the current generation circuit may be structured to be able to control the reference current in three or more stages. This makes it possible to more flexibly control the idling current. For example, in a case where the input common voltage is the voltage at which the NMOS input differential pair operates, the reference current is made larger than in a case where the input common voltage is the voltage at which the PMOS input differential pair operates. The current generation circuit may be further structured to be able to control the reference current in two or more stages when the input common voltage is the voltage at which the NMOS input differential pair operates.

In the above embodiment, an example has been mainly described in which the reference current is controlled so as to inhibit a decrease in the idling current based on a decrease in the source-drain voltage of the first output transistor including the P-channel MOS transistor. However, in a case where the source-drain voltage of the second output transistor including the N-channel MOS transistor decreases, the idling current may also decrease. Therefore, in a case where the source-drain voltage of the second output transistor decreases to such an extent that the idling current does not flow sufficiently, the reference current may be increased.

The decreasing condition of the idling current may be that the input common voltage is the voltage at which the PMOS input differential pair operates, and the input common voltage is lower than the predetermined voltage. As a result, even in a case where the source-drain voltage of the second output transistor including the N-channel MOS transistor decreases, the idling current can be appropriately adjusted, and the output voltage can be stabilized.

### Supplement

Although the embodiments according to the present disclosure have been described using specific terms, this description is merely an example for assisting understanding, and does not limit the present disclosure or the claims, and the scope of the invention is defined by the claims. In addition, not only the embodiments but also embodiments, examples, and modifications not described herein are included in the scope of the present disclosure. Furthermore, one or a plurality of constituent elements included in the operational amplifiers according to the first to fourth embodiments can be combined with one or a plurality of elements of the operational amplifier according to another embodiment.

### Note

The technology disclosed in the present specification can be understood as follows in one aspect.

### Note 1

An operational amplifier including:
an input circuit including a PMOS input differential pair to which a first input voltage and a second input voltage are input and an NMOS input differential pair to which the first input voltage and the second input voltage are input, an operating input differential pair being switchable between the PMOS input differential pair and the NMOS input differential pair;
a current generation circuit structured to generate a reference current; and
an output circuit through which an idling current that increases according to an increase in the reference current flows, and structured to generate an output voltage according to output signals of the PMOS input differential pair and the NMOS input differential pair, wherein
the current generation circuit is structured to make the reference current larger in a case where a decreasing condition of the idling current is satisfied than in a case where the decreasing condition is not satisfied.

### Note 2

The operational amplifier according to note 1, wherein
the decreasing condition is that a common voltage of the first input voltage and the second input voltage is higher than a predetermined voltage.

### Note 3

The operational amplifier according to note 1, wherein
the input circuit is structured to switch the operating input differential pair according to a common voltage of the first input voltage and the second input voltage, and
the decreasing condition is that the common voltage is a voltage at which the NMOS input differential pair operates.

### Note 4

The operational amplifier according to any one of notes 1 to 3, wherein
the input circuit further includes a tail current source structured to supply an electric current to operate the PMOS input differential pair and the NMOS input differential pair,
the current generation circuit includes a reference current source structured to supply a first reference current, and is structured to supply the first reference current as the reference current in a case where the PMOS input differential pair is operating, and to supply an electric current obtained by adding a second reference current to the first reference current as the reference current in a case where the NMOS input differential pair is operating, and
the second reference current is an electric current obtained by copying the electric current supplied by the tail current source by a current mirror circuit.

### Note 5

The operational amplifier according to any one of notes 1 to 4, wherein
the output circuit includes a first output transistor including a P-channel MOS transistor and a second output transistor including an N-channel MOS transistor, the first output transistor and the second output transistor being push-pull connected,
the current generation circuit further includes a first reference transistor including a P-channel MOS transistor and through which the reference current flows, and a second reference transistor including an N-channel MOS transistor and through which the reference current flows, and
the first output transistor, the second output transistor, the first reference transistor, and the second reference transistor are provided to make a gate-source voltage of the first output transistor equal to a gate-source voltage of the first reference transistor, and to make a gate-source voltage of the second output transistor equal to a gate-source voltage of the second reference transistor.

### Note 6

A semiconductor device including the operational amplifier according to any one of notes 1 to 5.

What is claimed is:

1. An operational amplifier comprising:
an input circuit including a P-channel metal oxide semiconductor (PMOS) input differential pair to which a first input voltage and a second input voltage are input and an N-channel metal oxide semiconductor (NMOS) input differential pair to which the first input voltage and the second input voltage are input, an operating input differential pair being switchable between the PMOS input differential pair and the NMOS input differential pair;
a current generation circuit structured to generate a reference current; and
an output circuit through which an idling current that increases according to an increase in the reference current flows, and structured to generate an output voltage according to output signals of the PMOS input differential pair and the NMOS input differential pair, wherein
the current generation circuit is structured to make the reference current larger in a case where a decreasing condition of the idling current is satisfied than in a case where the decreasing condition is not satisfied.

2. The operational amplifier according to claim 1, wherein
the decreasing condition is that a common voltage of the first input voltage and the second input voltage is higher than a predetermined voltage.

3. The operational amplifier according to claim 1, wherein
the input circuit is structured to switch the operating input differential pair according to a common voltage of the first input voltage and the second input voltage, and
the decreasing condition is that the common voltage is a voltage at which the NMOS input differential pair operates.

4. The operational amplifier according to claim 3, wherein
the input circuit further includes a tail current source structured to supply an electric current to operate the PMOS input differential pair and the NMOS input differential pair,
the current generation circuit includes a reference current source structured to supply a first reference current, and is structured to supply the first reference current as the reference current in a case where the PMOS input differential pair is operating, and to supply an electric current obtained by adding a second reference current to the first reference current as the reference current in a case where the NMOS input differential pair is operating, and
the second reference current is an electric current obtained by copying the electric current supplied by the tail current source by a current mirror circuit.

5. The operational amplifier according to claim 1, wherein
the output circuit includes a first output transistor including a P-channel MOS transistor and a second output transistor including an N-channel MOS transistor, the first output transistor and the second output transistor being push-pull connected,
the current generation circuit further includes a first reference transistor including a P-channel MOS transistor and through which the reference current flows, and a second reference transistor including an N-channel MOS transistor and through which the reference current flows, and
the first output transistor, the second output transistor, the first reference transistor, and the second reference transistor are provided to make a gate-source voltage of the first output transistor equal to a gate-source voltage of the first reference transistor, and to make a gate-source voltage of the second output transistor equal to a gate-source voltage of the second reference transistor.

6. A semiconductor device comprising the operational amplifier according to claim 1.
